(19) United States
(12) Patent Application Publication
(10) Pub. No.: US 2010/0252191 A1
(43) Pub. Date: Oct. 7, 2010

(54) SHEET STICKING APPARATUS AND SHEET STICKING METHOD

(75) Inventors: Kan Nakata, Tokyo (JP); Yota Aoki, Tokyo (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: LINTEC CORPORATION, Tokyo (JP)

(21) Appl. No.: 12/746,669

(22) PCT Filed: Nov. 28, 2008
(86) PCT No.: PCT/JP2008/071630

§ 371 Date: Jun. 7, 2010

(30) Foreign Application Priority Data
Dec. 20, 2007 (JP) 2007-328648

(51) Int. Cl. B32B 37/10; H01L 21/683

(52) U.S. Cl. 156/285; 156/556

(57) ABSTRACT

A sheet sticking apparatus 10 includes a first case 20 for accommodating a table 11 for supporting a semiconductor wafer W, a second case 21 for forming a decompression chamber C with the first case 20, and feeding means 15 for feeding an adhesive sheet S to a position where the adhesive sheet S faces the semiconductor wafer W. The second case 21 includes a bulkhead 30 for forming a pressure adjusting chamber C1 in a state where a single decompression chamber C is formed, the pressure adjusting chamber C1 being capable of controlling the pressure therein independently of the decompression chamber C, wherein the adhesive sheet S is stuck to the semiconductor wafer W under decompression by setting the decompression chamber C in a decompression state and relatively increasing the pressure in the pressure adjusting chamber C1.

### TECHNICAL FIELD

The present invention relates to a sheet sticking apparatus and a sheet sticking method, and more particularly a sheet sticking apparatus and a sheet sticking method that can stick an adhesive sheet to an adherend under decompression.

### BACKGROUND ART

Conventionally, semiconductor wafers (simply referred to as “wafers” below) are designed to stick an adhesive sheet to a circuit surface and a back surface of the wafers, and are subjected to various processes such as backgrinding and dicing.

Patent Document 1 discloses an adhesive sheet sticking apparatus. The apparatus includes a lower housing for accommodating a mount table, and an upper housing abutting an upper end of the lower housing. The apparatus is configured to interpose the adhesive sheet between the housings so that two upper and lower decompression chambers (process chambers) partitioned by the adhesive sheet can be formed, and the adhesive sheet is stuck to the wafers under decompression.

### Patent Document 1: Japanese Patent Application Laid-Open No. 60-80249

### SUMMARY OF THE INVENTION

### Problems to be Solved by the Invention

However, the sheet sticking apparatus in the Patent Document 1 forms the two decompression chambers above and below by the adhesive sheet. In the sheet sticking apparatus having such configuration, the adhesive sheet deforms due to the difference in pressure caused between two decompression chambers when the decompression chambers are decompressed prior to sticking of the sheet, so that the adhesive sheet is stuck to a wafer and pulled in the opposite direction from the wafer before the decompression is completed, thereby causing the sheet to be tore. From this, each decompression chamber must be decompressed while maintained at the same pressure. Therefore, there is a disadvantage that the pressure control is very complicate. Moreover, even when decompressing means common to the two decompression chambers is used, the same disadvantage as described above does not resolved because of the difference in time it takes to reach a predetermined decompression state due to the difference in volumes of the decompression chambers.

### OBJECT OF THE INVENTION

The present invention is made in view of such disadvantages, and has its object to provide a sheet sticking apparatus and a sheet sticking method that can stick an adhesive sheet to an adherend under decompression without any complicated control for decompression control.

### Means to Solve the Problems

To achieve the above object, the present invention adopts the following configuration: a sheet sticking apparatus, comprising: a table for supporting an adherend, an openable and closable case for accommodating the table and forming a decompression chamber in the case, and feeding means for feeding an adhesive sheet to a position where the adhesive sheet faces the adherend; the case being closed, and the adhesive sheet being stuck to the adherend under decompression; wherein in a state where the case is closed to form a single decompression chamber, a pressure adjusting chamber is provided so as to be capable of being formed with the adherend and the adhesive sheet on the adherend enclosed in the decompression chamber, the pressure adjusting chamber being capable of controlling the pressure therein independently of the decompression chamber.

Moreover, the present invention may adopt the following configuration: a sheet sticking apparatus, comprising: a table for supporting a semiconductor wafer, a first case for accommodating the table and having an opening, a second case for closing the opening and forming a decompression chamber in cooperation with the first case, and feeding means for feeding an adhesive sheet to a position where the adhesive sheet faces the adherend; the adhesive sheet being stuck to the semiconductor wafer under decompression; wherein in a state where the first case is closed by the second case to form a single decompression chamber, a bulkhead is provided to form a pressure adjusting chamber with the semiconductor wafer and the adhesive sheet on the semiconductor wafer enclosed in the decompression chamber, the pressure adjusting chamber being capable of controlling the pressure therein independently of the decompression chamber.

Preferably, the present invention adopts the following configuration: the table is provided such that an upper surface of the table is able to move forward and backward relative to the bulkhead.

Moreover, the present invention adopts the following steps: a sheet sticking method, comprising: supporting an adherend; feeding an adhesive sheet to a position where the adhesive sheet faces the adherend; accommodating the adherend and the adhesive sheet and forming a single decompression chamber; decompressing the decompression chamber; forming a pressure adjusting chamber with the adherend and the adhesive sheet on the adherend enclosed in the decompression chamber, the pressure adjusting chamber being capable of controlling the pressure therein independently of the decompression chamber; and sticking the adhesive sheet to the adherend by relatively increasing the pressure in the pressure adjusting chamber relative to the pressure in the decompression chamber.

### EFFECTS OF THE INVENTION

According to the invention, the decompression chamber may be handled as a single decompression chamber so that the invention does not require complicated pressure control that decompresses each decompression chamber while maintaining the pressure in each decompression chamber at the same pressure in the case where a plurality of decompression chambers are formed, because the decompression chamber is not divided into the plurality of chambers by the adhesive sheet. Therefore, the adhesive sheet may be stuck to an adherend only by forming the pressure adjusting chamber and relatively increasing the pressure in the pressure adjusting chamber in a state where the decompression chamber is decompressed.

Moreover, the table is provided such that the table may advance and retreat toward the bulkhead, and therefore the pressure adjusting chamber may be formed by pressing the table against the bulkhead after the decompression chamber is generally decompressed.

Note that decompression is used in the description as a concept including a vacuum.

### BRIEF DESCRIPTION OF THE DRAWINGS

FIG. 1 is a schematic front view showing a sheet sticking apparatus of the embodiment, a part of the apparatus being cross sectioned;

FIG. 2 is a schematic plan view with a part of FIG. 1 omitted;

FIG. 3 is a schematic front view showing a state where a decompression chamber is formed;

FIG. 4 is a schematic cross sectional view showing a state where a pressure adjusting chamber is formed; and

FIG. 5 is a partial enlarged view showing a state where an adhesive sheet is stuck to a wafer without bubbles.

### DESCRIPTION OF REFERENCE NUMERAL

10 sheet sticking apparatus
11 table
14 case
15 feeding means
20 first case
21 second case
30 bulkhead
C decompression chamber
C1 pressure adjusting chamber
S adhesive sheet
W semiconductor wafer (adherend)

### BEST MODE FOR WORKING THE INVENTION

A preferred embodiment of the present invention will be described below with reference to the drawings.

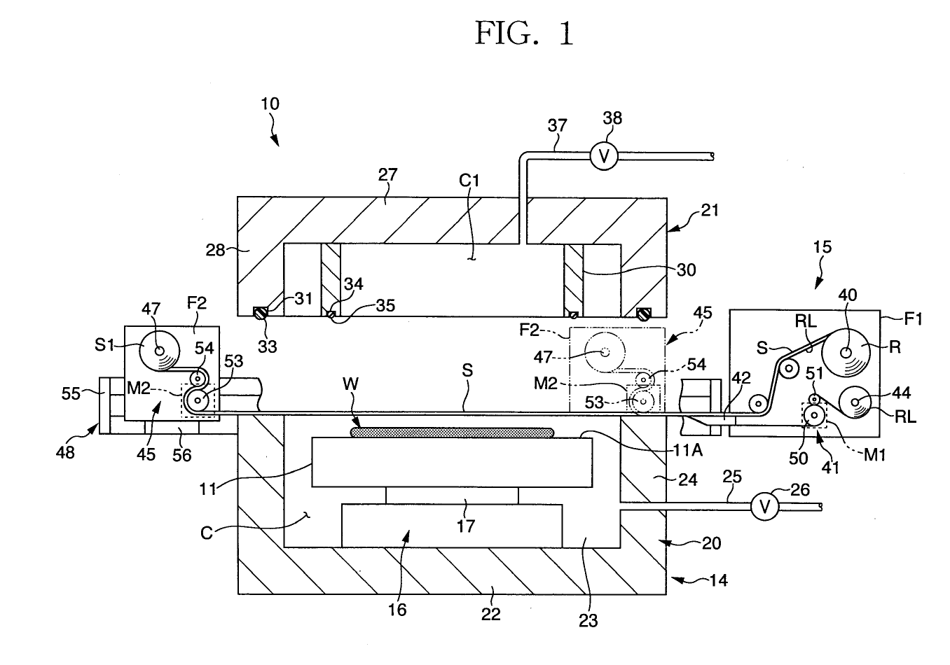

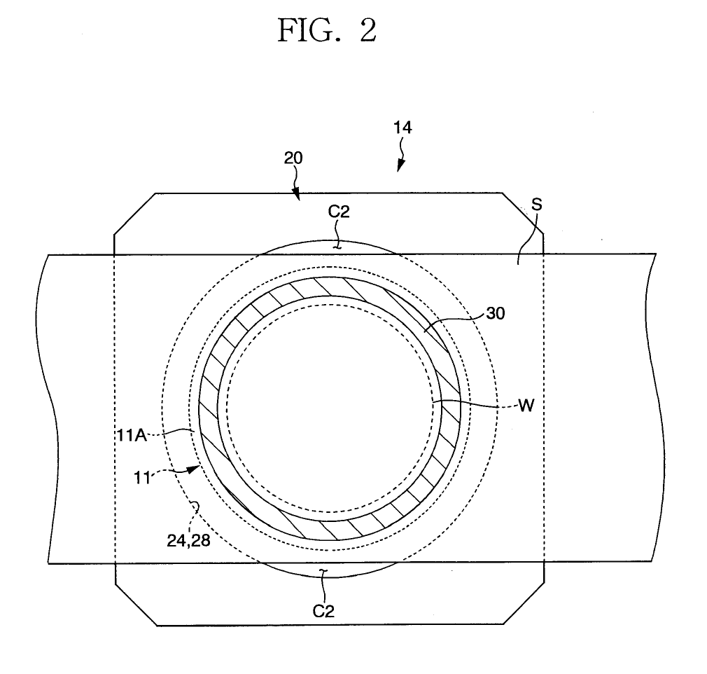

FIG. 1 shows a schematic front view of a sheet sticking apparatus according to the embodiment, and FIG. 2 shows a schematic plan view with a part of FIG. 1 omitted. In these drawings, a sheet sticking apparatus 10 comprises a table 11 for supporting a substantially circular wafer W as an adherend, a case 14 for accommodating the table 11 and forming a decompression chamber C therein, and feeding means 15 for feeding a pressure-sensitive adhesive sheet S to a position where the adhesive sheet S faces a surface to be adhered, which is an upper surface of the wafer W, in an opened state of the case 14. The adhesive sheet S is adopted, which has a width dimension that does not separate the decompression chamber C into upper and lower portions. As shown in FIG. 2, the adhesive sheet S is adapted to form clearances C2 without covering an inner-diameter area of the case 14 when fed to the position where the adhesive sheet S faces the surface to be adhered of the wafer W. The clearances C2 may be a passage such as a pipe and a through-hole to prevent the decompression chamber C from being separated into a plurality of portions.

The table 11 has a size to form an outer peripheral exposed surface 11A which is positioned outside of the wafer W with the wafer W centrally supported, wherein the wafer W may be held by holding means (not shown). An output shaft 17 of a linear motor 16 is fixed on a lower surface side of the table 11. The table 11 is provided such that the table 11 may be moved upward and downward by driving the linear motor 16.

The case 14 is composed of a first case 20 located on the lower part side in FIG. 1, and a second case 21 located on the upper part side therein. The first case 20 comprises a substantially square bottom portion 22 which supports the table 11 via the linear motor 16, and an erecting portion 24 which continues to the outer periphery of the bottom portion 22 and forms a substantially circular recess portion 23 in the central region thereof, the first case 20 being provided in a form of a container having a bottom with an upper end thereof forming an opening. The first case 20 is connected to a decompression pump (not shown) via a pipe 25 connected to the erecting portion 24 and a first solenoid valve 26, and is provided so as to be able to be lifted and lowered via elevating means (not shown).

The second case 21 is comprised of a top portion 27 whose planar shape is a substantially square shape, a drooping portion 28 continuing to the outer periphery of the top portion 27, and a cylindrical bulkhead 30 provided on the interior surface side of the top portion 27. The inside diameter of the bulkhead 30 is designed to be larger than the outside diameter of the wafer W, and the outside diameter of the bulkhead 30 is designed to be smaller than the diameter of the table 11. A recessed groove 31 is formed in a lower end surface of the drooping portion 28 over the entire periphery of the drooping portion 28. The recessed groove 31 receives an O-ring 33 therein as a packing material. Moreover, a similar recessed groove 34 is also formed in a lower end surface of the bulkhead 30. The recessed groove 34 receives an O-ring 35 therein.

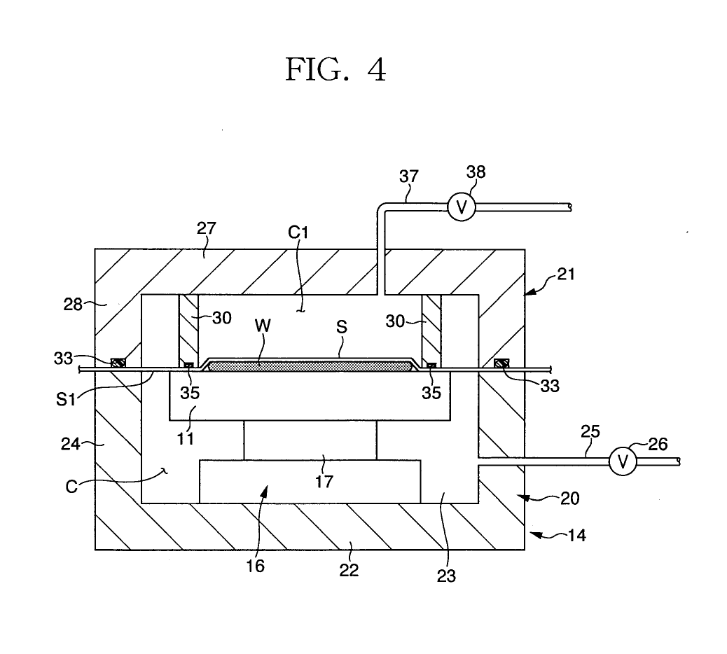

The second case 21 is supported movably in a vertical direction via moving means (not shown). The second case 21 is lowered on the first case 20 side, such that the lower end surface of the drooping portion 28 is pressed against an upper end side of the erecting portion 24 and the second case 21 forms the decompression chamber C by interaction with the first case 20. As shown in FIG. 4, the lower end surface of the bulkhead 30 is pressed against the outer peripheral exposed surface 11A of the table 11 in a state where the adhesive sheet S is interposed therebetween when the table 11 is lifted, so that the bulkhead 30 encloses the wafer W and the adhesive sheet S on the wafer W, thereby forming a pressure adjusting chamber C1 which can control the pressure therein independently of the decompression chamber C. The top portion 27 of the second case 21 is connected with a decompression pump (not shown) via a pipe 37 and a second solenoid valve 38, so that the pressure control of the pressure adjusting chamber C1 may be independently conducted through the second solenoid valve 38 and the decompression pump.

The feeding means 15 comprises: a support roller 40 having a lock mechanism supporting a roll-shaped raw sheet R with a strip-shaped release liner RL temporarily stuck to an adhesive agent layer side of the strip-shaped adhesive sheet S; winding means 41 for collecting the release liner RL; a peel plate 42 for peeling the release liner RL from the adhesive sheet S; drawing and winding means 45 for drawing the adhesive sheet S to the position where the adhesive sheet S faces the surface to be adhered, i.e., the upper surface of the wafer W, and for winding an unnecessary adhesive sheet S1 which is on a periphery side of the adhesive sheet S stuck to the wafer W; cutting means (not shown) for cutting the adhesive sheet S stuck to the wafer W in accordance with the size of the wafer W; and moving means 48 for supporting the drawing and winding means 45 movably in a horizontal direction in FIG. 1. Note that the cutting means may use a multi-jointed robot described in Japanese Patent Application No. 2006-115106 which has already filed by the present applicant.

The winding means 41 comprises a drive roller 50, a pinch roller 51 for interposing the release liner RL between the drive roller 50 and the pinch roller 51, and a release liner winding roller 44 for winding the release liner RL. The drive roller 50 and the release liner winding roller 44 are provided rotatably in synchronization by using a motor M1 supported by a frame F1.

The drawing and winding means 45 comprises a drive roller 53, a pinch roller 54 for interposing the unnecessary adhesive sheet S1 between the drive roller 53 and the pinch roller 54, and an unnecessary-sheet winding roller 47. The drive roller 53 and the unnecessary-sheet winding roller 47 are provided rotatably in synchronization by using a motor M2 supported by a frame F2.

The moving means 48 comprises a single axis robot 55 extending in a horizontal direction in FIG. 1. The frame F2 is fixed to a slider 56 of the single axis robot 55 so that the drawing and winding means 45 can move in a horizontal direction.

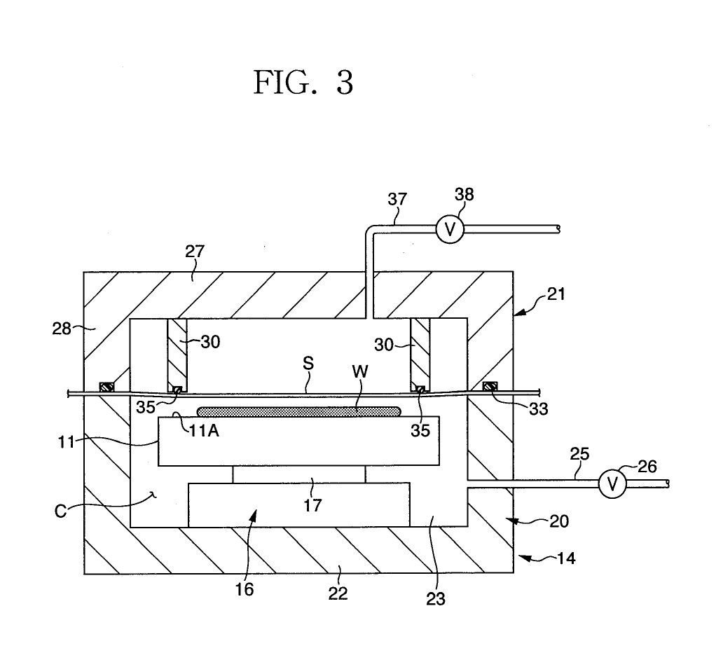

A sheet sticking method according to the embodiment will be now described with reference to FIGS. 3 to 5.

First, a lead end of the raw sheet R supported by the support roller 40 is drawn by a predetermined length, in a state where the second case 21 is positioned at a lifted position to open the case 14; the release liner RL is peeled from the adhesive sheet S at the tip end of the peel plate 42; and a lead end of the release liner RL is fixed to the release liner winding roller 44. On the other hand, the adhesive sheet S is fixed to the unnecessary-sheet winding roller 47 of the drawing and winding means 45 which is positioned at a position shown by a two-dot chain line in FIG. 1.

When a wafer W is placed on the table 11, the drawing and winding means 45 moves from a position of the two-dot chain line in FIG. 1 to a position shown by a solid line in a state of locking the rotation of the drive roller 53 and the unnecessary-sheet winding roller 47, and the winding means 41 is driven in synchronism with such operation so that the release liner is collected. Thus, the adhesive sheet S is fed into a state where the adhesive sheet S extends across and above the first case 20, i.e. to the position where the adhesive sheet S faces the upper surface of the wafer W.

Next, the first case 20 is lifted, and the second case 21 is lowered, so that the decompression chamber C is formed by interaction with the first and second cases 20 and 21 (see FIG. 3). At this time, the decompression chamber C is not separated into the upper and lower portions by the adhesive sheet S. Moreover, at this stage, the pressure adjusting chamber C1 is not formed as well, but a single decompression chamber C is formed in which the interiors of the first and second cases 20 and 21 are generally communicated with each other. In this state, the decompression chamber C is decompressed through the pipe 25 by controlling the solenoid valve 26. When the decompressed pressure reaches a predetermined set pressure, the table 11 is lifted so that the lower end surface of the bulkhead 30 is pressed against the outer peripheral exposed surface 11A of the table 11 via the adhesive sheet S, so that the pressure adjusting chamber C1 is formed which is capable of controlling the pressure therein independently of the decompression chamber C.

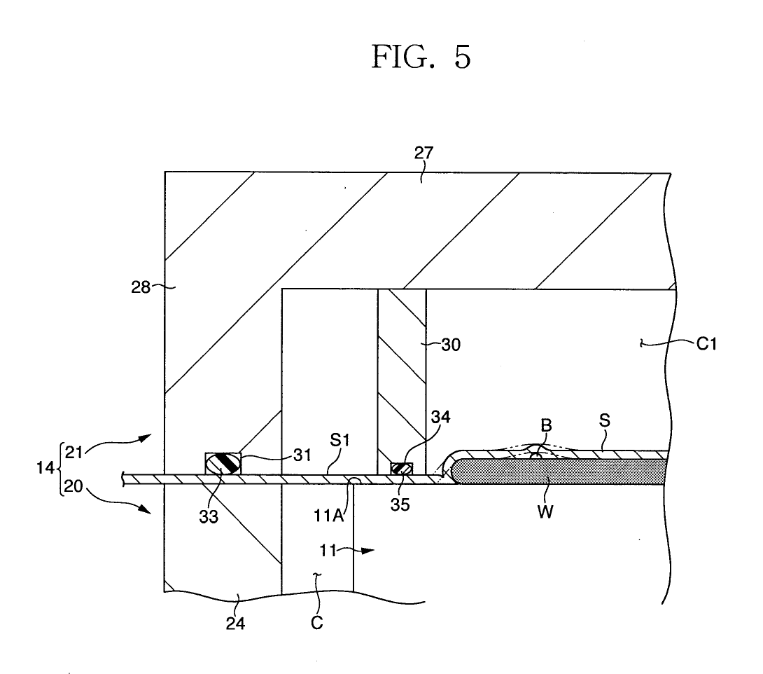

The pressure in the decompression chamber C is gradually brought close to atmospheric pressure (which eventually becomes atmospheric pressure) through the pipe 37 by controlling the solenoid valve 38. This operation causes the adhesive sheet S to be stuck to the wafer W. Where the adhesion is performed under such decompression, spaces which are present at the outer peripheral end of the wafer W and around a bump B formed on the wafer W, as shown by a two-dot chain line in FIG. 5, are eliminated when the pressure therein reaches normal pressure (atmospheric pressure). Therefore, the adhesive sheet S may be stuck to the wafer W without bubbles.

When sticking of the adhesive sheet S is completed, the pressure in the decompression chamber C except the pressure adjusting chamber C1 is gradually brought close to atmospheric pressure by controlling the solenoid valve 26. When the pressure therein reaches atmospheric pressure, the second case 21 is lifted to open the case 14. The adhesive sheet S, then, is cut into a closed loop shape along the outer periphery of the wafer W, by way of the cutting means (not shown).

After the adhesive sheet S is cut, the drive roller 53 and the unnecessary-sheet winding roller 47 move to the position shown by the two-dot chain line in FIG. 1 while the rollers 53 and 47 rotate, in a state where the support roller 40 and drive roller 50 are locked. Thus, the unnecessary adhesive sheet S1 produced by the above cutting is wound.

The wafer W, with the adhesive sheet S stuck, is transferred to a subsequent process or a predetermined storage locker by way of conveying means (not shown), and a subsequent wafer W to be subjected to sticking is transferred on the table 11, and thereafter the adhesive sheet S is stuck as well.

According to this embodiment, thus, the embodiment is configured to form the pressure adjusting chamber C1, which is capable of controlling the pressure independently, within a single the decompression chamber C, and sticks the adhesive sheet S on the wafer W. Therefore, such configuration does not require conventional complicated pressure control which decompresses a plurality of decompression chamber while maintaining the pressure in the plurality of decompression chambers at the same pressure, and also highly simplify decompression control in the decompression chamber C. In particular, the sticking of the sheet under such decompression enables a problem for bubble intrusion to be avoided when the wafer W includes a bump forming a concave-convex surface.

Although the best configuration, method, and the like for carrying out the invention have been disclosed in the above description, the invention is not limited thereto.

Thus, the invention has been particularly illustrated and described mainly in terms of a specific embodiment, but those skilled in the art may make various modifications to the embodiments described above in term of shapes, quantities, and other detailed configurations without deviating from the scope of a technical idea and an object of the invention.

Accordingly, the description limiting the shapes and the like disclosed above is described as an example in order to facilitate understanding of the invention, and is not intended to limit the invention. Therefore, the descriptions of parts name without part or all of the limiting of the shapes, and the like thereof are within the invention.

In the embodiment described above, the pressure sensitive adhesive sheet is used as the adhesive sheet S, as an example. However, the present invention is not limited thereto, and may adopt a heat-sensitive adhesive sheet for die bonding, and the like. In this instance, a heater may be built into the table 11 and air supplied through the pipe 37 may be hot air. Moreover, the adhesive sheet S may also be fed using an adhesive sheet of sheet-fed type.

Further, the adherend is not limited to the wafer W, but may also glass plates, steel plates or resin plates and the like, and other plate member having no bump. The semiconductor wafer may also be a silicon wafer or a compound wafer.

1. A sheet sticking apparatus, comprising: a table for supporting an adherend, an openable and closable case for accommodating the table and forming a decompression chamber in the case, and feeding means for feeding an adhesive sheet to a position where the adhesive sheet faces the adherend; the case being closed, and the adhesive sheet being stuck to the adherend under decompression;
wherein in a state where the case is closed to form a single decompression chamber, a pressure adjusting chamber is provided so as to be capable of being formed with the adherend and the adhesive sheet on the adherend enclosed in the decompression chamber, the pressure adjusting chamber being capable of controlling the pressure therein independently of the decompression chamber.

2. A sheet sticking apparatus, comprising: a table for supporting a semiconductor wafer, a first case for accommodating the table and having an opening, a second case for closing the opening and forming a decompression chamber in cooperation with the first case, and feeding means for feeding an adhesive sheet to a position where the adhesive sheet faces the adherend;
the adhesive sheet being stuck to the semiconductor wafer under decompression;
wherein in a state where the first case is closed by the second case to form a single decompression chamber, a bulkhead is provided to form a pressure adjusting chamber with the semiconductor wafer and the adhesive sheet on the semiconductor wafer enclosed in the decompression chamber, the pressure adjusting chamber being capable of controlling the pressure therein independently of the decompression chamber.

3. The sheet sticking apparatus according to claim 2, wherein the table is provided such that an upper surface of the table is able to advance and retreat toward the bulkhead.

4. A sheet sticking method, comprising steps of:
supporting an adherend;
feeding an adhesive sheet to a position where the adhesive sheet faces the adherend;
accommodating the adherend and the adhesive sheet and forming a single decompression chamber;
decompressing the decompression chamber;
forming a pressure adjusting chamber with the adherend and the adhesive sheet on the adherend enclosed in the decompression chamber, the pressure adjusting chamber being capable of controlling the pressure therein independently of the decompression chamber; and
sticking the adhesive sheet to the adherend by relatively increasing the pressure in the pressure adjusting chamber relative to the pressure in the decompression chamber.
